(19) United States
(12) Patent Application Publication
(10) Pub. No.: US 2025/0351521 A1
(43) Pub. Date: Nov. 13, 2025

(54) SEMICONDUCTOR DEVICES WITH REDUCED LEAKAGE CURRENT AND METHODS OF FORMING THE SAME

(71) Applicant: Taiwan Semiconductor Manufacturing Company, Ltd., Hsin-Chu (TW)

(72) Inventors: Yu-Hsuan Lin, Chiayi City (TW); Chun Po Chang, Hsinchu (TW); Chen-Ming Lee, Taoyuan County (TW); Fu-Kai Yang, Hsinchu City (TW); Jian-Hao Chen, Hsinchu City (TW); Mei-Yun Wang, Hsinchu (TW)

(21) Appl. No.: 19/276,917

(22) Filed: Jul. 22, 2025

Related U.S. Application Data
(62) Division of application No. 17/832,580, filed on Jun. 4, 2022.

(51) Int. Cl. H10D 64/23; H01L 21/02; H01L 21/3213; H10D 30/01; H10D 30/43; H10D 30/67; H10D 62/10; H10D 64/01

(52) U.S. Cl. CPC H10D 64/258; H01L 21/02603; H01L 21/32133; H01L 21/32139; H10D 30/014; H10D 30/031; H10D 30/43; H10D 30/6706; H10D 30/6729; H10D 30/6735; H10D 30/6757; H10D 62/121; H10D 64/015; H10D 64/018

(57) ABSTRACT

Semiconductor devices and methods are provided. An exemplary method according to the present disclosure includes providing a workpiece having a channel region, a gate structure over the channel region, gate spacers extending along sidewalls of the gate structure, and an etch stop layer extending along sidewalls of the gate spacers. The method also includes performing an etching process to recess the gate spacers and the gate structure, thereby forming a funnel-shaped trench, depositing a dielectric layer over the workpiece to partially fill the funnel-shaped trench, etching back the dielectric layer to form dielectric spacers on the recessed gate spacers, forming a metal cap on the gate structure without forming the metal cap on the recessed gate spacers, and forming a dielectric cap on the metal cap.

### PRIORITY DATA

The present application is a divisional application of U.S. patent application Ser. No. 17/832,580, filed Jun. 4, 2022, which is herein incorporated by reference in its entirety.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

For example, as integrated circuit (IC) technologies progress towards smaller technology nodes, multi-gate devices have been introduced to improve gate control by increasing gate-channel coupling, reducing off-state current, and reducing short-channel effects (SCEs). A multi-gate device generally refers to a device having a gate structure, or portion thereof, disposed over more than one side of a channel region. Fin-like field effect transistors (FinFETs) and gate-all-around (GAA) transistors (both also referred to as non-planar transistors) are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). Compared to planar transistors, such configuration provides better control of the channel and drastically reduces SCEs (in particular, by reducing sub-threshold leakage (i.e., coupling between a source and a drain of the FinFET in the “off” state)). A GAA transistor has a gate structure that can extend, partially or fully, around a channel region to provide access to the channel region on two or more sides. The channel region of the GAA transistor may be formed from nanowires, nanosheets, other nanostructures, and/or other suitable structures. Although existing multi-gate devices (e.g., FinFETs and GAA transistors) and processes are generally adequate for their intended purposes, they have not been entirely satisfactory in every aspect.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion. It is also emphasized that the drawings appended illustrate only typical embodiments of this invention and are therefore not to be considered limiting in scope, for the invention may apply equally well to other embodiments.

FIG. 1 is a flowchart illustrating a method of forming a semiconductor device, according to various embodiments of the present disclosure.

FIGS. 2, 3, 4, 5, 6, 7, 8, 9, 10, and 11 illustrate fragmentary cross-sectional views of a workpiece during various fabrication stages in the method of FIG. 1, according to various aspects of the disclosure.

FIG. 12 is a flowchart illustrating a first alternative method of forming a semiconductor device, according to various embodiments of the present disclosure.

FIGS. 13, 14, 15, 16, 17, 18, and 19 illustrate fragmentary cross-sectional views of a workpiece during various fabrication stages in the method of FIG. 12, according to various aspects of the disclosure.

FIG. 20 is a flowchart illustrating a second alternative method of forming a semiconductor device, according to various embodiments of the present disclosure.

FIGS. 21, 22, 23, 24, 25, 26, 27, 28, 29, 30, 31, 32, and 33 illustrate fragmentary cross-sectional views of a workpiece during various fabrication stages in the method of FIG. 20, according to various aspects of the disclosure.

FIG. 34 is a flowchart illustrating a third alternative method of forming a semiconductor device, according to various embodiments of the present disclosure.

FIGS. 35, 36, 37, 38, 39, 40, 41, and 42 illustrate fragmentary cross-sectional views of a workpiece during various fabrication stages in the method of FIG. 34, according to various aspects of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to semiconductor devices and methods of forming the same. A method according to embodiments of the present disclosure includes, after forming a gate stack, recessing the gate stack and gate spacers to form a funnel-shaped trench, forming dielectric spacers in the funnel-shaped trench to partially fill the funnel-shaped trench while exposing the gate stack, and forming a metal cap over the gate stack after forming the dielectric spacers. By forming the dielectric spacers in the funnel-shaped trench, the metal cap may be laterally confined by the dielectric spacers during the formation of the metal cap, thereby reducing a distance between the metal cap and a neighboring source/drain contact. Therefore, the corresponding semiconductor device may have a reduced parasitic capacitance, reduced leakage current, and thus better performance.

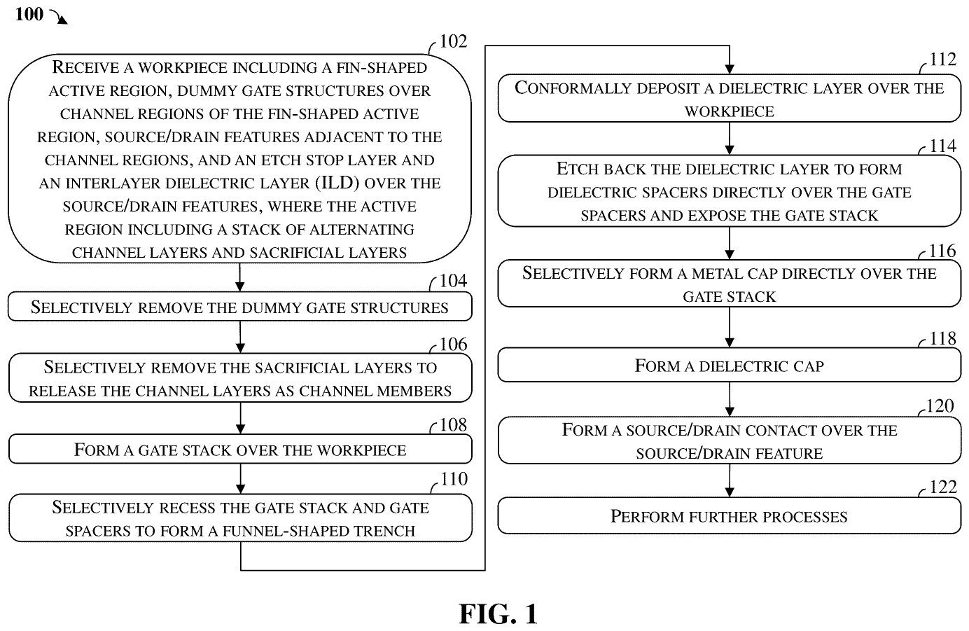

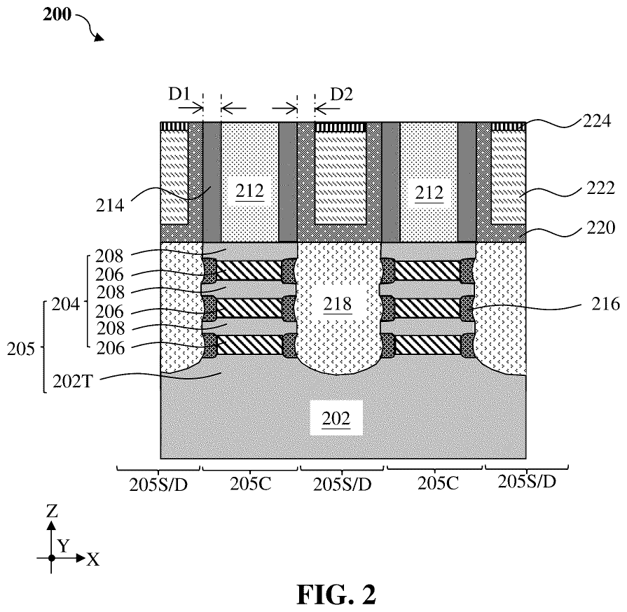

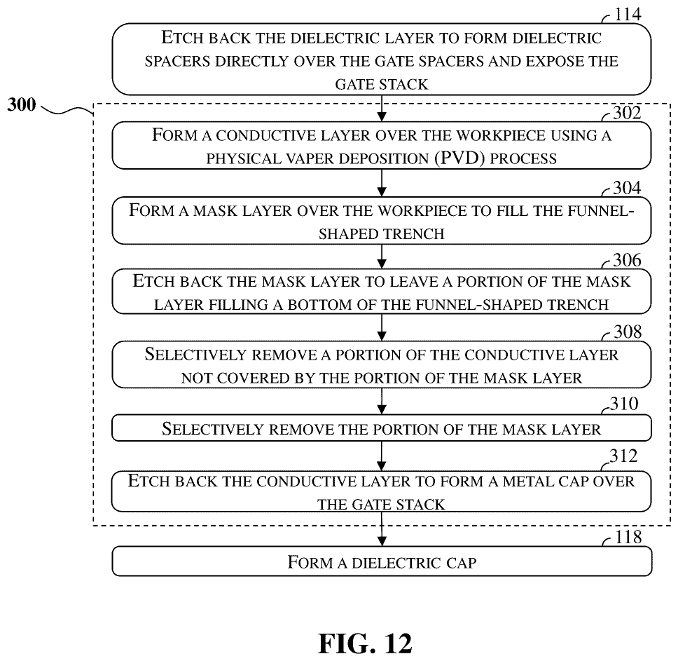

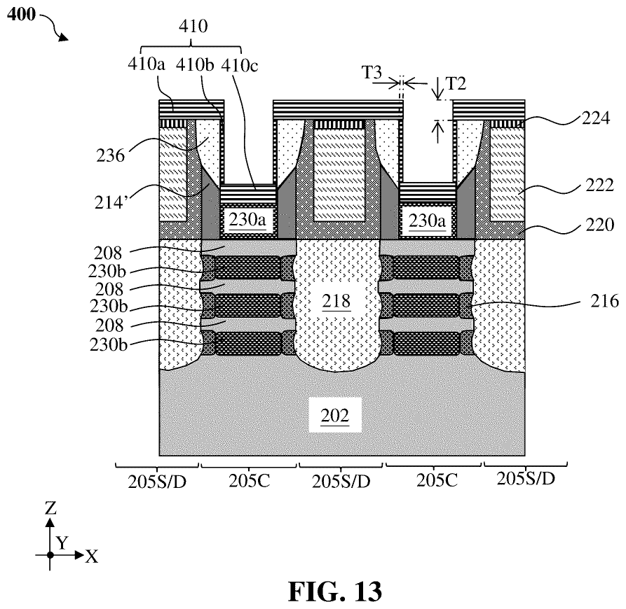

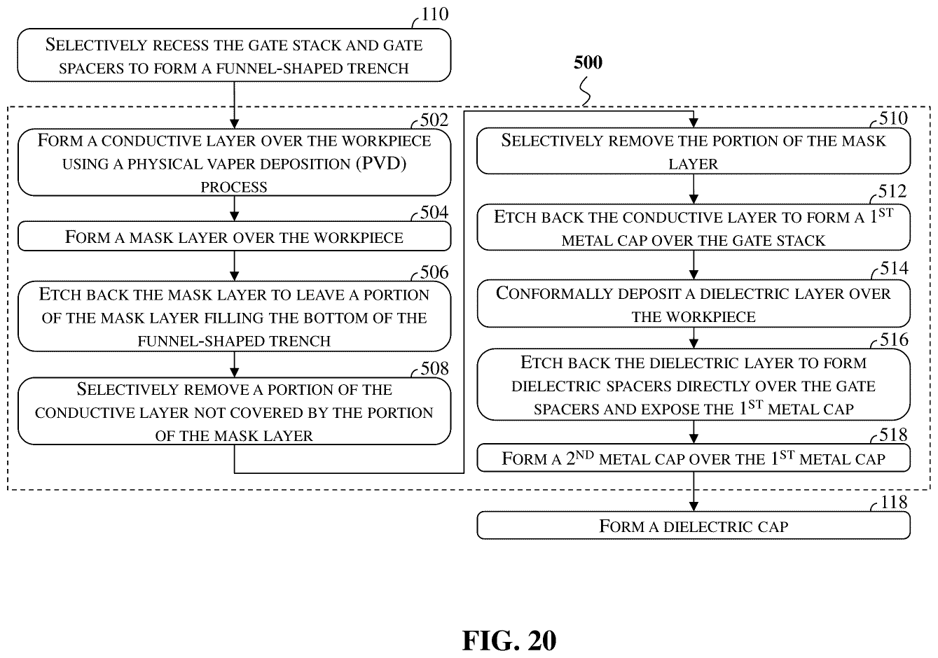

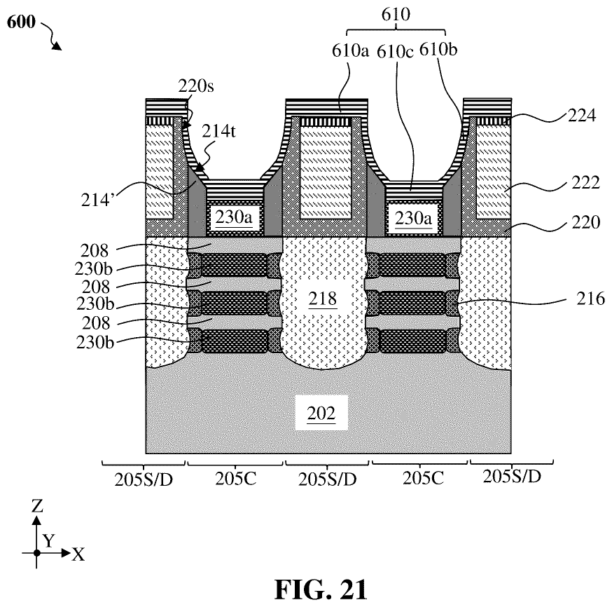

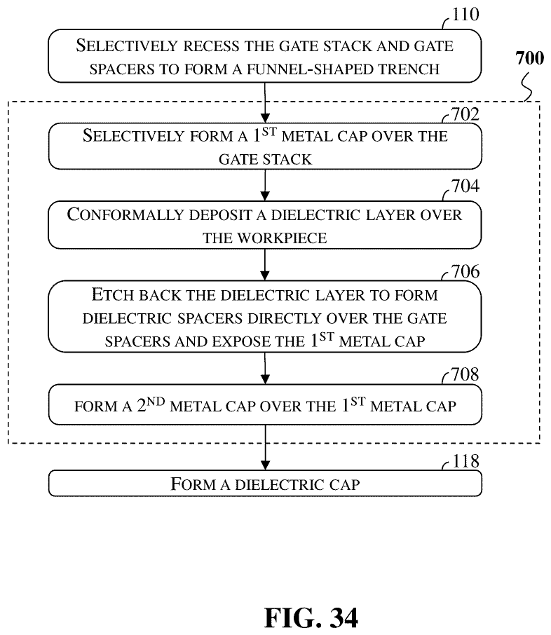

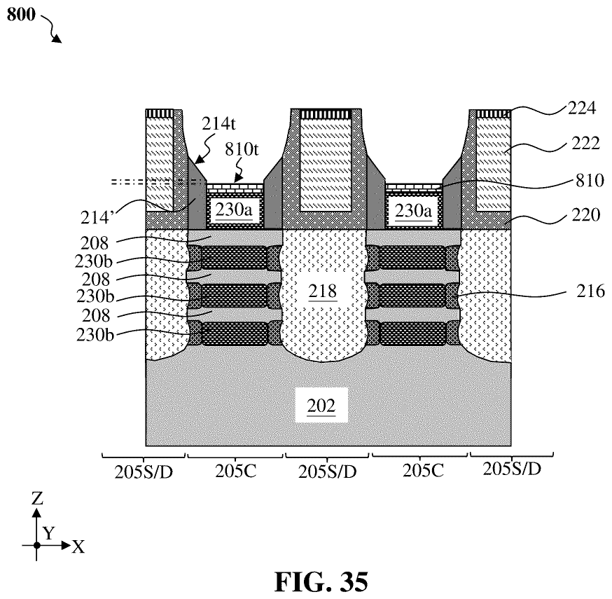

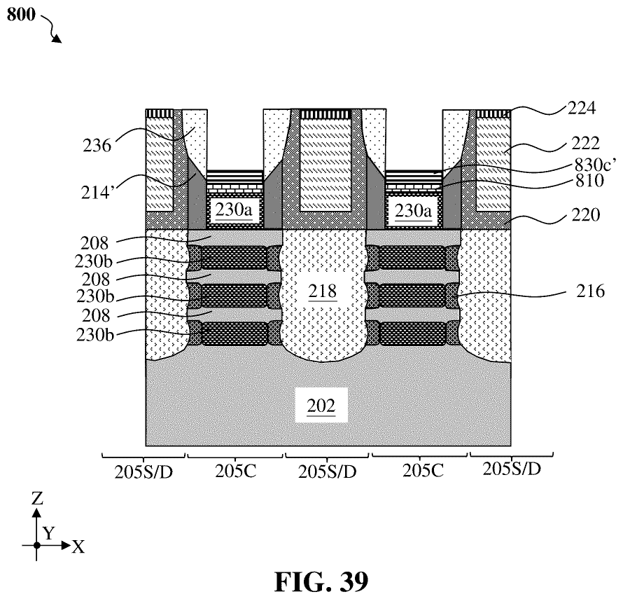

The various aspects of the present disclosure will now be described in more detail with reference to the figures. In that regard, FIG. 1 is a flowchart illustrating method 100 of forming a semiconductor device according to embodiments of the present disclosure. Method 100 is described below in conjunction with FIGS. 2-11, which are fragmentary cross-sectional views of a workpiece 200 at different stages of fabrication according to embodiments of method 100. FIG. 12 includes a flowchart illustrating an alternative method 300 of forming a semiconductor device according to embodiments of the present disclosure. Method 300 is described below in conjunction with FIGS. 13-19, which are fragmentary cross-sectional views of a workpiece 400 at different stages of fabrication according to embodiments of method 300. FIG. 20 includes a flowchart illustrating an alternative method 500 of forming a semiconductor device according to embodiments of the present disclosure. Method 500 is described below in conjunction with FIGS. 21-33, which are fragmentary cross-sectional views of a workpiece 600 or a workpiece 600′ at different stages of fabrication according to embodiments of method 500. FIG. 34 includes a flowchart illustrating an alternative method 700 of forming a semiconductor device according to embodiments of the present disclosure. Method 700 is described below in conjunction with FIGS. 35-42, which are fragmentary cross-sectional views of a workpiece 800 or a workpiece 800′ at different stages of fabrication according to embodiments of method 700. Methods 100, 300, 500, and 700 are merely examples and are not intended to limit the present disclosure to what is explicitly illustrated therein. Additional steps may be provided before, during and after the methods 100100, 300, 500, and 700, and some steps described can be replaced, eliminated, or moved around for additional embodiments of the method. Not all steps are described herein in detail for reasons of simplicity. Because the workpiece 200/400/600/600′/800/800′ will be fabricated into a semiconductor device upon conclusion of the fabrication processes, the workpiece 200/400/600/600′/800/800′ may be referred to as the semiconductor device 200/400/600/600′/800/800′ as the context requires. For avoidance of doubts, the X, Y and Z directions in the figures are perpendicular to one another and are used consistently. Throughout the present disclosure, like reference numerals denote like features unless otherwise excepted.

Referring to FIGS. 1 and 2, method 100 includes a block 102 where a workpiece 200 is received. The workpiece 200 includes a substrate 202. In an embodiment, the substrate 202 is a bulk silicon substrate (i.e., including bulk single-crystalline silicon). The substrate 202 may include other semiconductor materials in various embodiments, such as germanium, silicon carbide, gallium arsenide, gallium phosphide, indium phosphide, indium arsenide, indium antimonide, SiGe, GaAsP, AlInAs, AlGaAs, GalnAs, GaInP, GaInAsP, or combinations thereof. In some alternative embodiments, the substrate 202 may be a semiconductor-on-insulator substrate, such as a silicon-on-insulator (SOI) substrate, a silicon germanium-on-insulator substrate, or a germanium-on-insulator substrate, and includes a carrier, an insulator on the carrier, and a semiconductor layer on the insulator.

The workpiece 200 also includes a fin-shaped active region 205 disposed over the substrate 202. The fin-shaped active region 205 extends lengthwise along the X direction and is divided into channel regions 205C and source/drain regions 205S/D. The fin-shaped active region 205 may be formed from a portion 202T of the substrate 202 and a vertical stack 204 of alternating semiconductor layers 206 and 208 using a combination of lithography and etch steps. In the depicted embodiment, the vertical stack 204 includes a number of channel layers 208 interleaved by a number of sacrificial layers 206. Each channel layer 208 may include a semiconductor material such as, silicon, germanium, silicon carbide, silicon germanium, GeSn, SiGeSn, SiGeCSn, other suitable semiconductor materials, or combinations thereof, while each sacrificial layer 206 has a composition different from that of the channel layer 208. In an embodiment, the channel layer 208 includes silicon (Si), the sacrificial layer 206 includes silicon germanium (SiGe). The channel layers 208 and the sacrificial layers 206 may be epitaxially deposited on the substrate 202 using molecular beam epitaxy (MBE), vapor-phase epitaxy (VPE), ultra-high vacuum CVD (UHV-CVD), and/or other suitable epitaxial growth processes. In some examples, each of the fin-shaped active region 205 may include a total of three to ten pairs of alternating sacrificial layers 206 and channel layers 208; of course, other configurations may also be applicable depending upon specific design requirements. In alternative embodiments where fin-type field effect transistors (FinFETs) are desired, the fin-shaped active region 205 may include a uniform semiconductor composition along the Z axis and free of the vertical stack 204 as depicted herein.

The workpiece 200 may also include an isolation feature (not shown) formed around the fin-shaped active region 205 to isolate two adjacent fin-shaped active regions. The isolation feature may also be referred to as a shallow trench isolation (STI) feature. In some embodiments, the STI feature may include silicon oxide, silicon oxynitride, fluorine-doped silicate glass (FSG), a low-k dielectric, combinations thereof, and/or other suitable materials.

Still referring to FIG. 2, the workpiece 200 also includes dummy gate structures 212 disposed over channel regions 205C of the fin-shaped active region 205. In some embodiments, the dummy gate structures 212 may share substantially the same composition and dimension. The channel regions 205C and the dummy gate structures 212 also define source/drain regions 205S/D that are not vertically overlapped by the dummy gate structures 212. In the present embodiments, a gate replacement process (or gate-last process) is adopted where the dummy gate structures 212 serve as placeholders for functional gate stacks. Other processes for forming the functional gate stacks are possible. In the present embodiments, although not separately shown, each of the dummy gate structures 212 includes a dummy gate dielectric layer (e.g., silicon oxide) and a dummy gate electrode (e.g., polysilicon) disposed over the dummy gate dielectric layer. As discussed in detail below, the dummy gate structures 212 are configured to be replaced with functional gate stacks 230.

Still referring to FIG. 2, the workpiece 200 also includes gate spacers 214 extending along sidewalls of the dummy gate structures 212. In some embodiments, the gate spacers 214 may include silicon oxide, silicon oxycarbide, silicon carbonitride, silicon oxycarbonitride, silicon nitride, zirconium oxide, aluminum oxide, or a suitable dielectric material. The gate spacers 214 may be a single-layer structure or a multi-layer structure. In an embodiment, each gate spacer 214 has a width D1 along the X direction. Additionally, the workpiece 200 also includes inner spacer features 216 disposed between two adjacent channel layers 208 and in direct contact with the sacrificial layers 206 in the channel regions 205C. The inner spacer features 216 may include silicon nitride, silicon oxycarbonitride, silicon carbonitride, silicon oxide, silicon oxycarbide, silicon carbide, silico oxynitride, other suitable materials, or combinations thereof.

In embodiments represented in FIG. 2, the workpiece 200 also includes source/drain features 218 formed in and/or over source/drain regions 205S/D and coupled to the channel layers 208 in the channel regions 205C. Source/drain feature(s) may refer to a source or a drain, individually or collectively dependent upon the context. Depending on the conductivity type of the to-be-formed transistor, the source/drain features 218 may be n-type source/drain features or p-type source/drain features. Exemplary n-type source/drain features may include silicon, phosphorus-doped silicon, arsenic-doped silicon, antimony-doped silicon, or other suitable material and may be in-situ doped during the epitaxial process by introducing an n-type dopant, such as phosphorus, arsenic, or antimony, or ex-situ doped using a junction implant process. Exemplary p-type source/drain features may include germanium, gallium-doped silicon germanium, boron-doped silicon germanium, or other suitable material and may be in-situ doped during the epitaxial process by introducing a p-type dopant, such as boron or gallium, or ex-situ doped using a junction implant process.

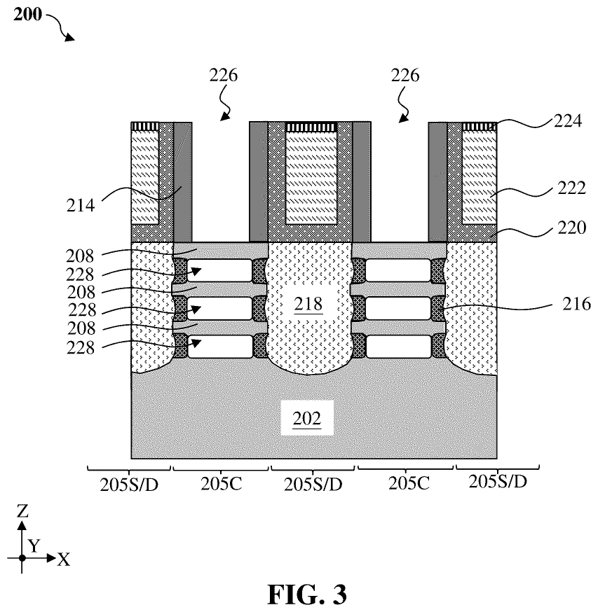

Still referring to FIG. 2, the workpiece 200 also includes a contact etch stop layer (CESL) 220 and an interlayer dielectric (ILD) layer 222. The CESL 220 is configured to protect the various underlying components during subsequent fabrication processes and may include silicon nitride, silicon oxynitride, and/or other suitable materials and may be formed by ALD, chemical vapor deposition (CVD), plasma-enhanced chemical vapor deposition (PECVD) process and/or other suitable deposition or oxidation processes. As shown in FIG. 3, the CESL 220 may be formed on top surfaces of the source/drain features 218 and sidewalls of the gate spacers 214 and has a uniform thickness D2. The ILD layer 222 may be deposited by a CVD process, a PECVD process or other suitable deposition technique over the workpiece 200 after the deposition of the CESL 220. The ILD layer 222 may include silicon oxide, a low-k dielectric material, TEOS, doped silicon oxide (e.g., BPSG, FSG, PSG, BSG, etc.), other suitable dielectric materials, or combinations thereof. A planarization process may be performed to remove excess portions of the CESL 220 and the ILD layer 222.

In embodiments represented in FIG. 2, the workpiece 200 also includes a hard mask layer 224 formed on the ILD layer 222. In some embodiments, the ILD layer 222 may be recessed and the hard mask layer 224 may be then formed over the recessed ILD layer 222. An etching process may be performed to selectively remove a top portion of the ILD layer 222 without removing, or substantially removing, the dummy gate structures 212, the CESL 220, or the gate spacers 214. The hard mask layer 224 may include aluminum oxide, silicon oxide, silicon nitride, silicon carbonitride, silicon oxycarbide, silicon oxynitride, silicon oxycarbonitride, other suitable materials, or combinations thereof, and may be formed by CVD, ALD, PVD, other suitable methods, or combinations thereof. In embodiment represented in FIG. 2, a top surface of the hard mask layer 224 is coplanar with top surfaces of the dummy gate structures 212.

Referring to FIGS. 1 and 3, method 100 includes a block 104 where the dummy gate structures 212 are selectively removed to form gate trenches 226 over the channel regions 205C. The dummy gate structures 212 are selectively removed by an etching process. The etching process for removing the dummy gate structures 212 may include any suitable process, such as a dry etching process, a wet etching process, or combinations thereof, and is configured to selectively remove the dummy gate structures 212 without substantially etching the channel layers 208, the sacrificial layers 206, the gate spacers 214, the CESL 220, the ILD layer 222, and the hard mask layer 224.

Referring to FIGS. 1 and 3, method 100 includes a block 106 where the sacrificial layers 206 are selectively removed to release the channel layers 208 as channel members 208. After the selective removal of the dummy gate structures 212, without substantially removing the channel layers 208, one or more etching processes may be performed to selectively remove the sacrificial layers 206 to release the channel layers 208 as channel members 208. The removal of the sacrificial layers 206 forms a number of openings 228.

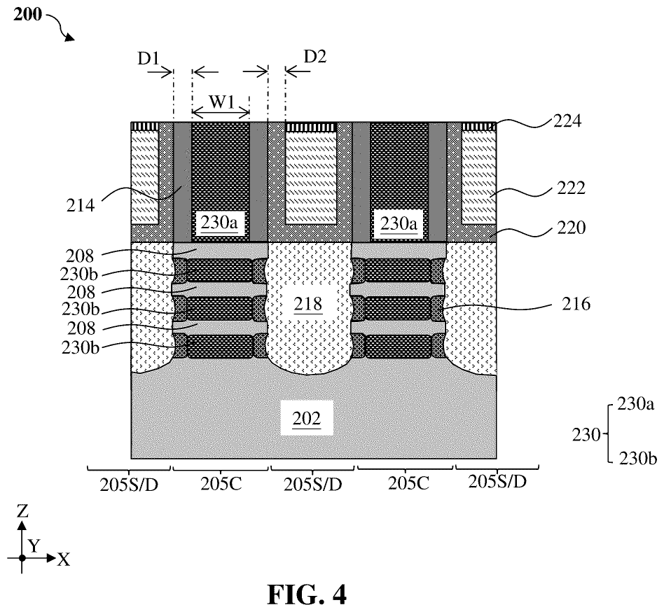

Referring to FIGS. 1 and 4, method 100 includes a block 108 where gate stacks 230 are formed over the workpiece 200. Each gate stack 230 is formed in the number of openings 228 and in the gate trench 226 to wrap around and over each of the channel members 208. As such, portions of the gate stack 230 formed in the openings 228 are interleaved with or wrapping around the channel layers 208. In the present embodiments, the portion of the gate stack 230 in the gate trench 226 is referred to as a gate stack 230a, and the portion of the gate stack 230 in openings 228 is referred to as a gate stack 230b. In the present embodiments, the gate stack 230 includes a gate dielectric layer (not shown) and a metal gate electrode (not shown) over the gate dielectric layer. The gate dielectric layer may include a high-k (having a dielectric constant greater than that of silicon oxide, which is approximately 3.9) dielectric material, such as hafnium oxide, lanthanum oxide, other suitable materials, or combinations thereof. The metal gate electrode includes at least one work function metal layer. The work function metal layer may be a p-type or an n-type work function metal layer. Example work function metals include TiN, TaN, WN, ZrSi₂, MoSi₂, TaSi₂, NiSi₂, Ti, TaAl, TaAlC, TiAlN, TaC, TaCN, TaSiN, Mn, Zr, other suitable work function metals, or combinations thereof. The gate stack 230 may further include other material layers (not depicted). Material layers of the gate stack 230 may be formed by various methods, including ALD, CVD, PVD, plating, other suitable methods, or combinations thereof. A planarization process may be then performed to planarize the top surface of the workpiece 200 by implementing one or more CMP process. The planarization process may stop until the top surface of the hard mask layer 224 is exposed. In the present embodiments, after the planarization process, a top surface of the gate stack 230a is coplanar with the top surface of the hard mask layer 224 and has a width W1 along the X direction.

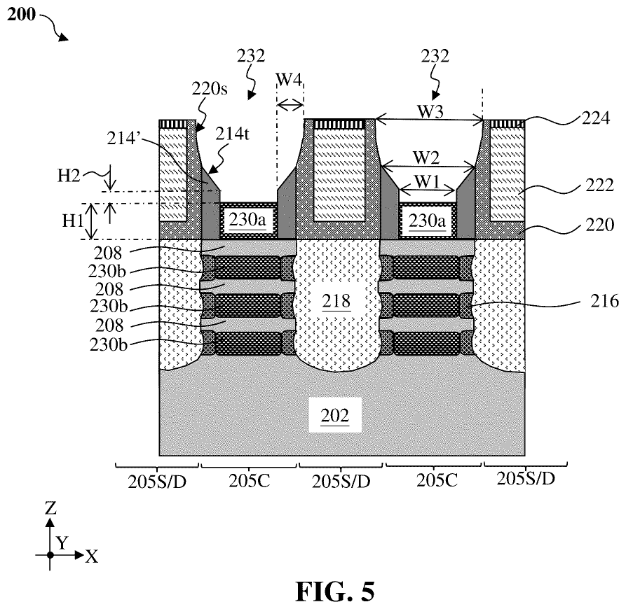

Referring to FIGS. 1 and 5, method 100 includes a block 110 where a top portion of the gate stack 230a and a top portion of the gate spacers 214 are removed to form a funnel-shaped trench 232. One or more etching processes may be performed to recess or etch back the gate stack 230a and the gate spacers 214. The one or more etching processes may be implemented by any suitable method, including a dry etching process, a wet etching process, RIE, other suitable methods, or combinations thereof, utilizing one or more etchant configured to etch components of the gate stack 230a and the gate spacers 214. In the present embodiments, the one or more etching processes are further configured to laterally etch a portion of the CESL 220. In embodiments represented in FIG. 5, the funnel-shaped trench 232 exposes a sidewall surface 220s of the CESL 220, a top surface 214t of the gate spacer 214, and a top surface of the gate stack 230a. In some embodiments, the sidewall surface 220s curves inward. The top surface 214t may be a tilted surface.

In an embodiment, a first etching process may be performed to recess the gate stack 230a and the gate spacers 214 to form a first opening, and a second etching process may be followed to enlarge a top portion of the first opening along the X direction, thereby forming the funnel-shaped trench 232. That is, a width W3 of the funnel-shaped trench 232 in a top region of the funnel-shaped trench 232 is greater than a width W2 of the funnel-shaped trench 232 in a middle region of the funnel-shaped trench 232, and the width W2 is greater than the width W1 of the gate stack 230a. After the forming of the funnel-shaped trench 232, the gate spacer 214 may be referred to as the gate spacer 214′. In the present embodiments, after the first etching process, a height H1 of the gate stack 230a is smaller than a height of the gate spacer 214′. That is, a top surface of the gate stack 230a is lower than the top surface 214t of the gate spacer 214′. In other words, a height difference H2 between the gate stack 230a and a shorter side of the gate spacer 214′ is greater than 0. In an embodiment, the height H1 of the gate stack 230a is between about 20 nm and about 40 nm. After the formation of the funnel-shaped trench 232, a largest distance between a sidewall of the gate stack 230a and a sidewall of the neighboring CESL 220 is referred to as W4. W4 is equal to a half of the width difference between the width W3 and the width W1. In other words, W4 is equal to 0.5*(W3−W1). W4 is greater than D1 and less than a sum of D1 and D2 (D1 and D2 are shown in FIG. 2). That is, D1<W4< (D1+D2).

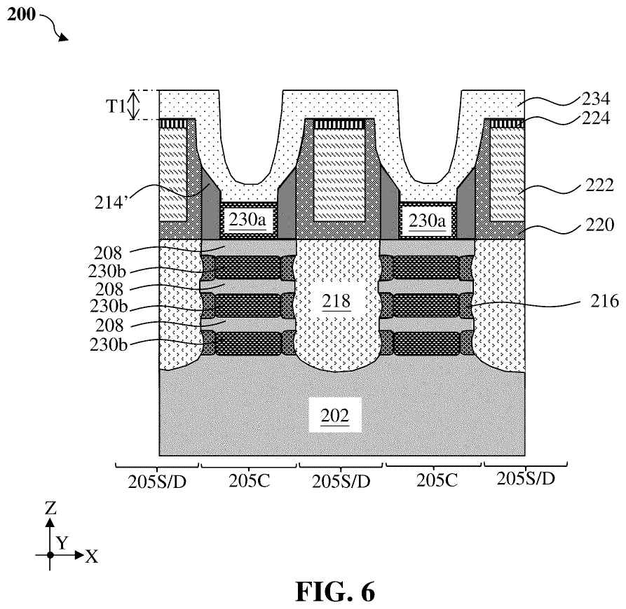

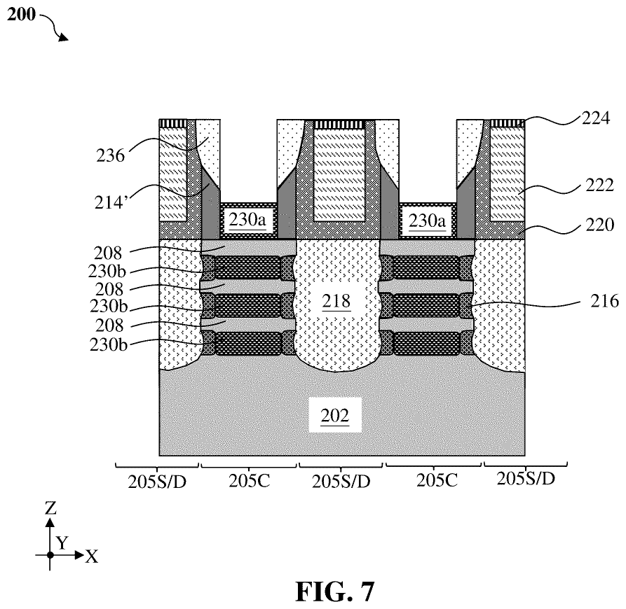

Referring to FIGS. 1 and 6, method 100 includes a block 112 where a dielectric layer 234 is conformally deposited over the workpiece 200. In an embodiment, the dielectric layer 234 is conformally deposited over the workpiece 200 to have a generally uniform thickness T1 over the top surface of the workpiece 200. A portion of the dielectric layer 234 tracks the shape of the funnel-shaped trench 232. In some embodiments, to form satisfactory dielectric spacers (e.g., dielectric spacers 236 shown in FIG. 7) over the gate spacers 214′, the thickness T1 may be equal to or greater than the width W4. The dielectric layer 234 may be formed of low-k dielectric materials. In some embodiments, the dielectric layer 234 may be formed of silicon nitride, silicon carbonitride (SiCN), silicon oxycarbonitride (SiOCN), silicon oxycarbide (SiOC), other suitable materials, or combinations thereof. The dielectric layer 234 may be deposited using atomic layer deposition (ALD), CVD, or other suitable processes. In an embodiment, a composition of the dielectric layer 234 is different from a composition of the gate spacer 214′.

Referring to FIGS. 1 and 7, method 100 includes a block 114 where the dielectric layer 234 is etched back to form dielectric spacers 236 in the funnel-shaped trench 232. Without substantially etching the gate stack 230a and the hard mask layer 224, an etching process (e.g., anisotropic etching process) may be performed to remove portions of the dielectric layer 234 formed on the top surfaces of the hard mask layer 224, the CESL 220, and the gate stack 230a to form the dielectric spacers 236. The dielectric spacers 236 covers the top surface 214t of the gate spacer 214′ and the sidewall surface 220s of the CESL 220 that was exposed by the funnel-shaped trench 232. In the present embodiments, since the thickness T1 of the dielectric layer 234 is no less than the width W4, after the etching process, the top surface 214t of the gate spacer 214′ is substantially fully covered by the dielectric spacer 236. In an embodiment, a sidewall surface of the dielectric spacer 236 is a vertical surface and is substantially aligned with a sidewall surface of the gate spacer 214′. As represented in FIG. 7, the width of the gate spacer 214′ is not uniform bottom to top. More specifically, the width gradually increases bottom to top.

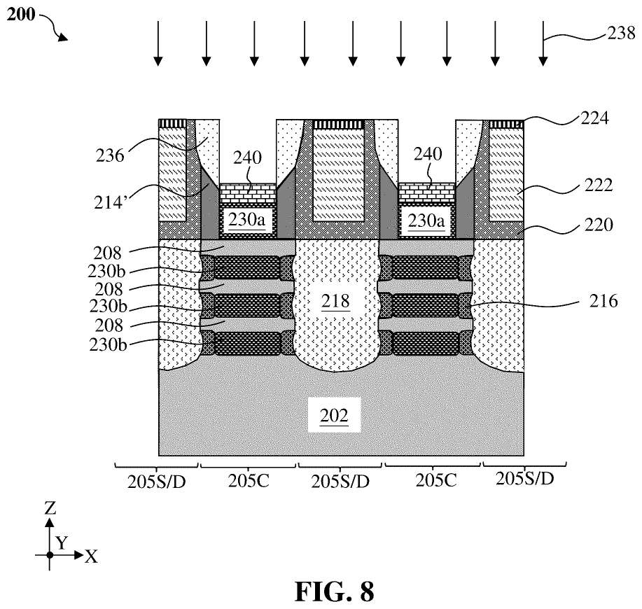

Referring to FIGS. 1 and 8, method 100 includes a block 116 where a metal cap 240 is selectively formed on the gate stack 230a by a deposition process 238 to partially fill a rest of the funnel-shaped trench 232. The formation of the metal cap 240 may reduce the gate resistance and improve performance of the transistors. A resistivity of the material of the metal cap 240 is less than a resistivity of a work function layer in the gate stack 230. In some embodiments, the metal cap 240 may include tungsten (W), cobalt (Co), nickel (Ni), molybdenum (Mo), ruthenium (Ru), or other suitable materials. In an exemplary embodiment, the selective deposition process 238 includes performing an ALD process 238 to selectively form the metal cap 240 over the workpiece 200 positioned within a process chamber. The ALD process 238 is a cyclic process. Each cycle includes a first half cycle and a second half cycle. Multiple cycles may be repeated until a satisfactory thickness of the metal cap 240 is obtained.

Taking the formation of tungsten-based metal cap 240 as one example. The workpiece 200 shown in FIG. 7 is loaded into a process chamber, where the process chamber is prepared for the ALD process 238 to form the tungsten-based metal cap 240 on the gate stack 230a. In the first half cycle, the workpiece 200 is exposed to a tungsten-containing precursor. The tungsten-containing precursor is selected such that it may be selectively deposited on the top surface of a work function layer of the gate stack 230a. In an embodiment, the tungsten-containing precursor includes tungsten chlorides (WCl5). In the second half cycle, a co-reactant is transported to the process chamber. In an embodiment, the co-reactant includes hydrogen (H2). The co-reactant reacts with the tungsten-containing precursor deposited on the work function layer. The reaction between the precursor and the co-reactant selectively forms the metal cap 240 on the work function layer of the gate stack 230a. In embodiment where the tungsten-containing precursor includes tungsten chlorides (WCl5) and the co-reactant includes hydrogen (H2), the reaction between the tungsten-containing precursor and the co-reactant may selectively form tungsten (W). The ALD process 238 selectively forms the metal cap 240 without forming a metal cap on the dielectric spacers 236 or the hard mask layer 224. In an embodiment, the metal cap 240 is a fluorine-free tungsten layer.

Still referring to FIG. 8, the metal cap 240 substantially covers the top surface of the gate stack 230a and a width of the metal cap 240 along the X direction may be substantially equal to the width W1 (previously shown in FIGS. 4 and 5). In an embodiment, a thickness of the metal cap 240 along the Z direction is greater than the height difference H2 (shown in FIG. 5). Since the top surface 214t of the gate spacer 214′ is covered by the dielectric spacer 236, the metal cap 240 would not extend over the gate spacer 214′. That is, the formation of the dielectric spacer 236 confines the growth of the metal cap 240 along the X direction. As such, a distance between the metal cap 240 and a to-be-formed source/drain contact may be increased, compared to other workpieces that have a metal cap that vertically overlaps with the gate spacer 214′. Therefore, a parasitic capacitance and leakage current of the workpiece 200 may be less than those of the other workpieces. In an embodiment, the thickness of the metal cap 240 is between about 2 nm and about 10 nm.

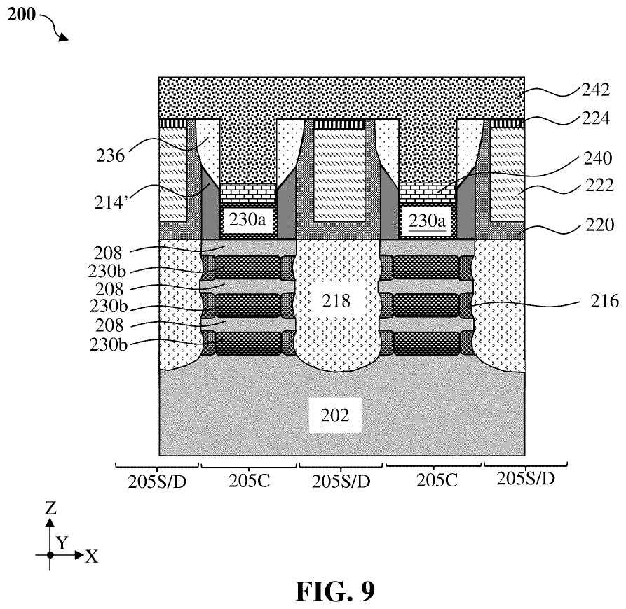

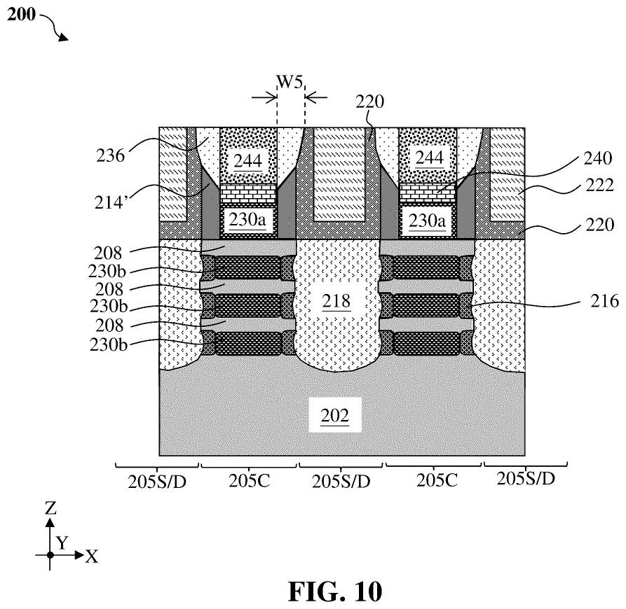

Referring to FIGS. 1, 9, and 10, method 100 includes a block 118 where a self-aligned dielectric cap 244 is formed on the metal cap 240. The formation of the self-aligned dielectric cap 244 includes, as represented in FIG. 9, forming a dielectric material layer 242 over the workpiece 200 by any suitable method, including CVD, FCVD, ALD, PVD, other methods, or combinations thereof. In some embodiments, the self-aligned dielectric cap 244 is configured to provide etching selectivity during subsequent fabrication processes including, for example, patterning the ILD layer 222 to form S/D contact openings over the S/D features 218. Accordingly, the self-aligned dielectric cap 244 has a composition different from that of the ILD layer 222. In some embodiments, the dielectric material layer 242 may include silicon nitride (SiN), silicon carbonitride (SiCN), silicon oxycarbonitride (SiOCN), silicon oxycarbide (SiOC), silicon oxynitride (SiON), other suitable materials, or combinations thereof. Subsequently, referring to FIG. 10, after forming the dielectric material layer 242, a planarization process (e.g., CMP) is performed to remove excess materials (including the hard mask layer 224) to expose a top surface of the ILD layer 222 to form the self-aligned dielectric cap 244. In an embodiment, after the planarization process, a width W5 of the dielectric spacer 236 exposed by the top surface of the workpiece 200 may be greater than D1 (shown in FIG. 2) and may be between about 1 nm and bout 15 nm.

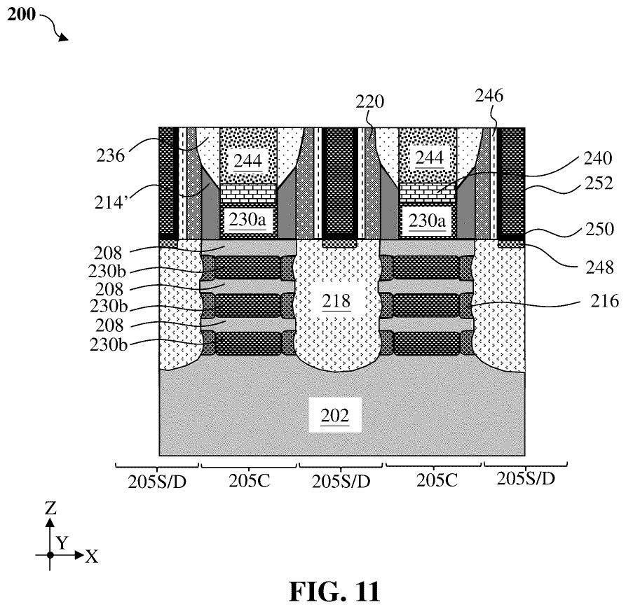

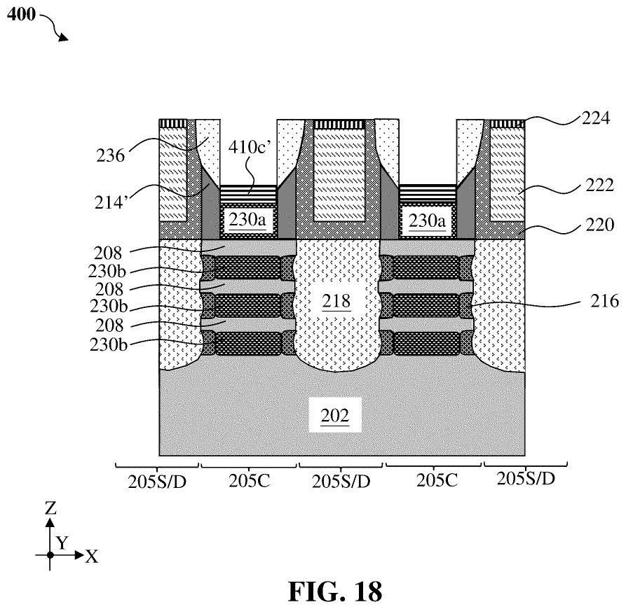

Referring to FIGS. 1 and 11, method 100 includes a block 120 where a source/drain contact is formed over the source/drain feature. The formation of the source/drain contact includes selectively removing portions of the ILD layer 222 and the CESL 220 formed directly over the source/drain features 218 to form a source/drain contact opening. After forming the source/drain contact opening, in embodiments represented in FIG. 18, a dielectric barrier layer 246 may be formed to extend along sidewall surfaces of the source/drain contact opening. In some embodiments, the dielectric barrier layer 246 may include silicon nitride or other suitable materials. A silicide layer 248 is then formed to reduce a contact resistance between the source/drain feature 218 and the to-be-formed source/drain contact. The silicide layer 248 may include nickel silicide. After the formation of the silicide layer 248, the source/drain contact may be formed in the source/drain contact opening. The source/drain contact may include a conductive liner 250 and a metal fill layer 252. The conductive liner 250 may include titanium, titanium nitride, other suitable materials, or combinations thereof. The metal fill layer 252 may include aluminum, rhodium, ruthenium, copper, iridium, or tungsten. The metal fill layer 252 is spaced apart from the silicide layer 248 and the dielectric barrier layer 246 by the conductive liner 250.

Referring to FIG. 1, method 100 includes a block 122 where further processes may be performed. Such further processes may include forming a multi-layer interconnect (MLI) structure (not depicted) over the workpiece 200. The MLI may include various interconnect features, such as vias and conductive lines, disposed in dielectric layers, such as etch-stop layers and ILD layers. In some embodiments, the vias are vertical interconnect features configured to interconnect device-level contacts, such as gate contacts (not depicted) formed over the gate stacks 230a. In the above embodiments, method 100 is applied to form dielectric spacers 236 and metal cap 240 in GAA transistors. In some other implementations, method 100 may be applied to form dielectric spacers and metal cap in FinFETs or planar transistors.

In the above embodiments, the metal cap 240 is selectively formed over the gate stack 230a. In some other embodiments, the metal cap 240 may be formed by different processes. FIG. 12 includes a flowchart illustrating an alternative method 300 of forming a semiconductor device according to embodiments of the present disclosure. Referring to FIGS. 12, and 13, after forming the dielectric spacers 236 shown in FIG. 7, method 300 is performed. Method 300 includes a block 302 where a conductive layer 410 is formed over a workpiece 400 using a physical vaper deposition (PVD) process. Before the forming of the conductive layer 410, the workpiece 400 shown in FIG. 13 has substantially the same structure as the workpiece 200 shown in FIG. 7. In the present embodiments, the conductive layer 410 is formed by a PVD process. Due to the properties of the PVD process, a portion of the conductive layer 410 formed on a top or planar surface is thicker than a portion of the conductive layer 410 formed on a side surface. For example, a portion 410a of the conductive layer 410 formed on the top surface of the dielectric spacer 236 and a portion 410c of the conductive layer 410 formed on the top surface of the gate stack 230a each has a thickness T2 that is greater than a thickness T3 of a portion 410b of the conductive layer 410 formed on the sidewall surface of the dielectric spacer 236. Since the dielectric spacers 236 are formed before the deposition of the conductive layer 410 and cover the top surface of the gate spacers 214′, during the deposition process, the boundary of the portion 410c of conductive layer 410 is laterally confined. That is,

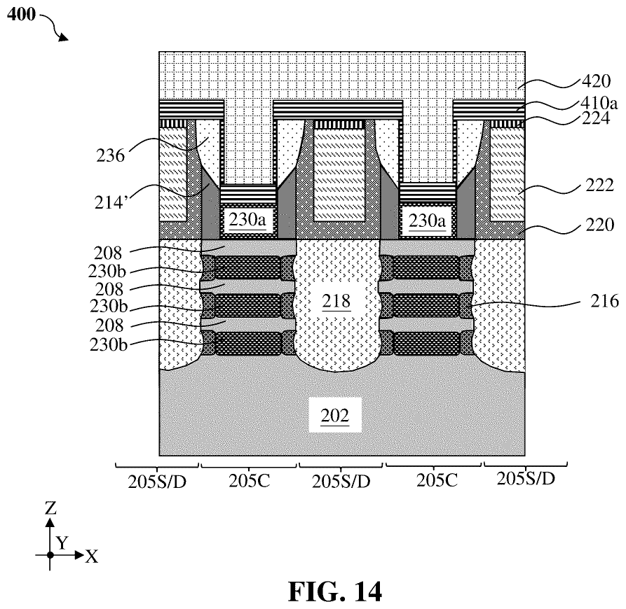

Referring to FIGS. 12 and 14, method 300 includes a block 304 where a mask layer 420 is formed over the workpiece 400. In the present embodiments, the mask layer 420 includes a bottom antireflective coating (BARC) layer 420. With reference to FIG. 14, the BARC layer 420 is formed over the conductive layer 410. The BARC layer 420 may include silicon oxynitride, a polymer, or a suitable material. After the forming of the BARC layer 420, the funnel-shaped trench 232 is substantially filled by the dielectric spacers 236, the conductive layer 410, and the BARC layer 420.

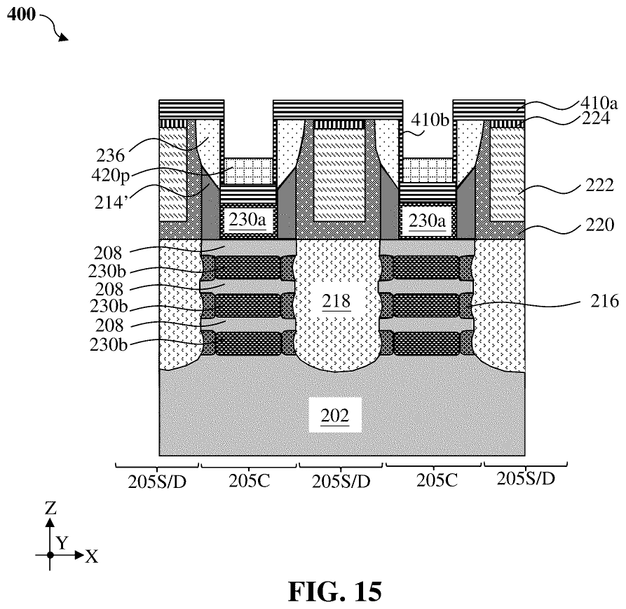

Referring to FIGS. 12 and 15, method 300 includes a block 306 where the mask layer 420 is etched back to leave a portion 420p of the mask layer 420 covering a portion of the conductive layer 410. The portion 420p of the mask layer 420 may be referred to as the mask layer 420p. More specifically, an etching process is performed to remove an upper portion of the BARC layer 420 to expose the portion 410a of the conductive layer 410 as well as an upper part of the portion 410b of the conductive layer 410. That is, the mask layer 420p covers a lower part of the portion 410b and also covers the portion 410c of the conductive layer 410.

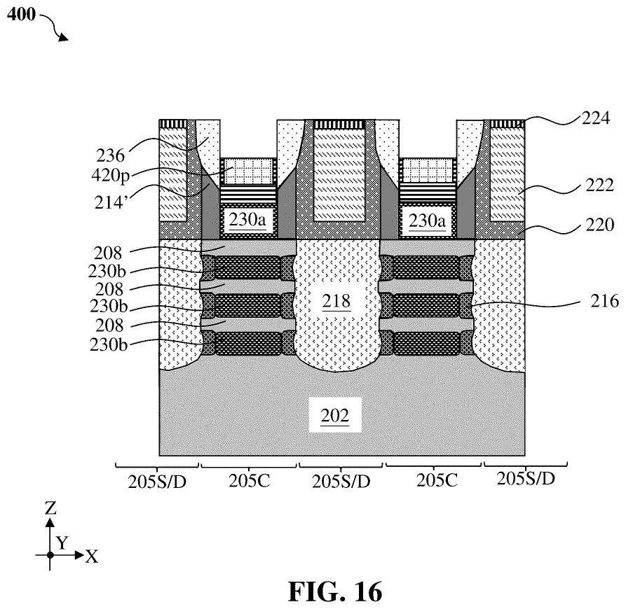

Referring to FIGS. 12 and 16, method 300 includes a block 308 where a portion of the conductive layer 410 not covered by the mask layer 420p is selectively removed. While using the mask layer 420p as an etch mask, an etching process is performed to selectively etch away the portion of the conductive layer 410 not covered by the portion 420p (e.g., the portion 410a and the upper part of the portion 410b of the conductive layer 410), as illustrated in FIG. 16. The etching process may be a dry etch process, a wet etch process, or a suitable etch process.

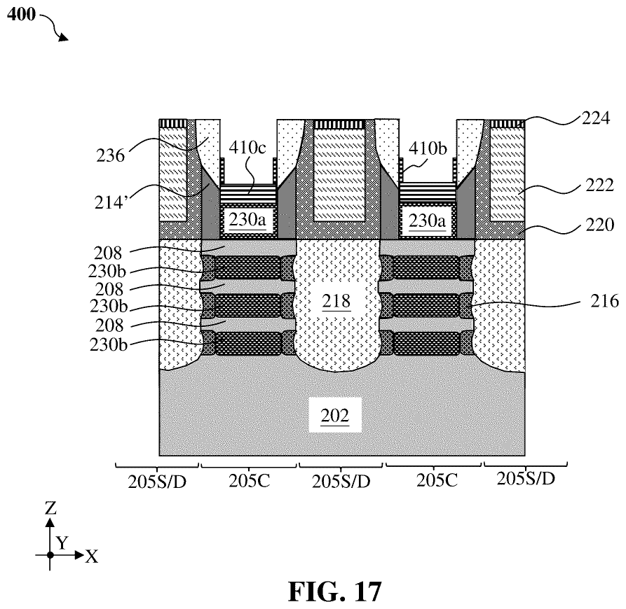

Referring to FIGS. 12 and 17, method 300 includes a block 310 where the mask layer 420p is selectively removed. After selectively removing the portion of the conductive layer 410, the mask layer 420p is selectively removed using a suitable etching process. In embodiments represented in FIG. 17, after the removal of the mask layer 420p, the conductive layer 410 includes a lower part of the portion 410b on the lower sidewall surface of the dielectric spacer 236 and the portion 410c on the top surface of the gate stack 230a.

Referring to FIGS. 12 and 18, method 300 includes a block 312 where the conductive layer 410 is further etched back to form a metal cap over the gate stack 230a. In an embodiment, an isotropic etching process is performed to selectively etch the conductive layer 410. The duration of the isotropic etching process may be controlled such that the portion 410b of the conductive layer 410 formed on the sidewall surface of the dielectric spacer 236 is fully removed. Due to the performing of the isotropic etching process, the portion 410c of the conductive layer 410 is also slightly etched. The portion 410c of the conductive layer 410 after the performing of the isotropic etching process may be referred to as a metal cap 410c′. In an embodiment, a top surface of the metal cap 410c′ may be above or below the top surface 214t of the gate spacer 214′.

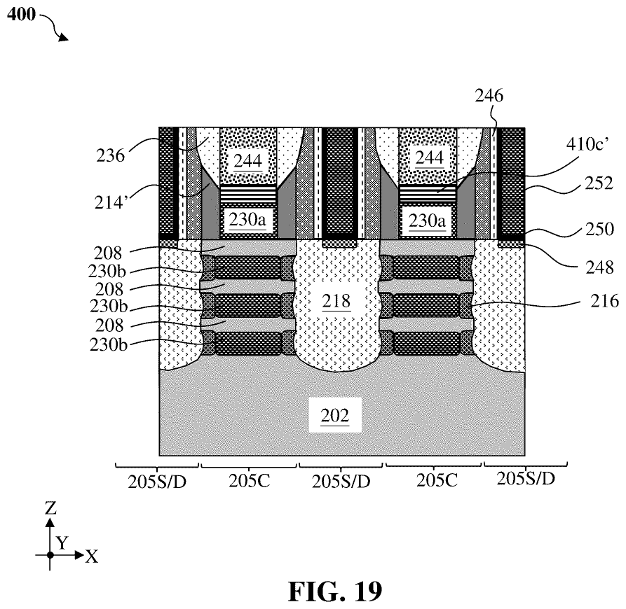

Referring to FIG. 12 and FIG. 19, after forming the metal cap 410c′, operations in blocks 118, 120, and 122 of method 100 in FIG. 1 may be performed to finish the fabrication process. The workpiece 400 shown in FIG. 19 is in a way similar to the workpiece 200 shown in FIG. 11, except that the metal cap 410c′ of the workpiece 400 is formed by a method different than the formation of the metal cap 240 of the workpiece 200.

In the embodiments described above with reference to FIG. 1 and FIG. 12, the metal cap is a single-layer structure. In some other embodiments, the metal cap may be a multi-layer structure. FIG. 20 and FIG. 34 each illustrates an alternative method 500/700 of forming a semiconductor device that has a multi-layer metal cap. Referring to FIG. 20 and FIG. 21, after forming the funnel-shaped trench 232 shown in FIG. 5, method 500 is performed. Method 500 includes a block 502 where a conductive layer 610 is formed over the workpiece 600 using a PVD process. Before the forming of the first conductive layer 610, the workpiece 600 shown in FIG. 21 has substantially the same structure as the workpiece 200 shown in FIG. 5. Similar to the conductive layer 410, due to the properties of the PVD process, a portion (e.g., a portion 610a, a portion 610c) of the conductive layer 610 formed on a planar surface is thicker than a portion (e.g., portion 610b) of the conductive layer 610 formed on a sidewall surface (e.g., the sidewall surface 220s and the top surface 214t). The portion 610b covers the sidewall surface 220s of the CESL 220 and the top surface 214t of the gate spacer 214′.

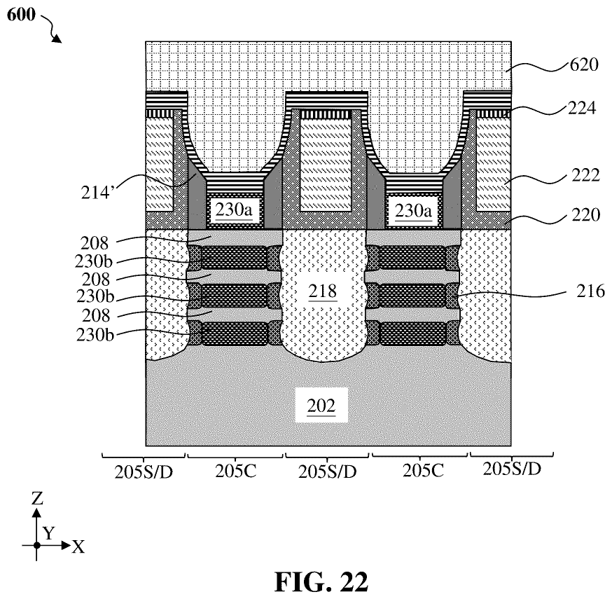

Referring to FIG. 20 and FIG. 22, method 500 includes a block 504 where a mask layer 620 is formed over the workpiece 600. In the present embodiments, the mask layer 620 includes a BARC layer. With reference to FIG. 22, the BARC layer is formed directly on the conductive layer 610. The BARC layer may include silicon oxynitride, a polymer, or a suitable material. After forming the mask layer 620, the funnel-shaped trench 232 is substantially filled by the conductive layer 610 and the mask layer 620.

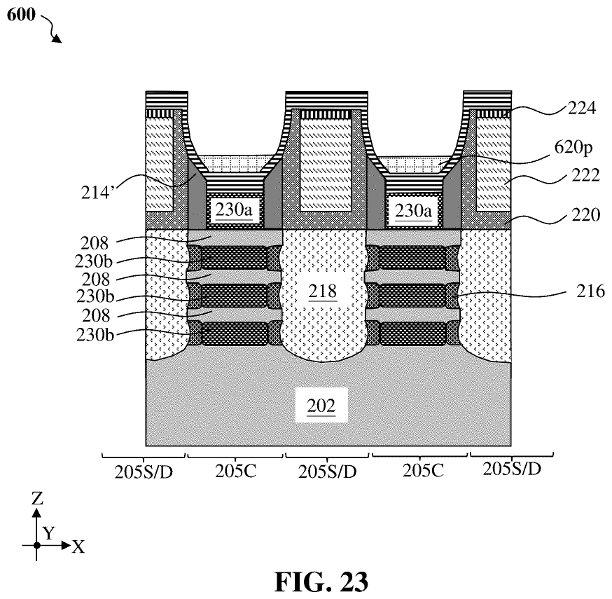

Referring to FIG. 20 and FIG. 23, method 500 includes a block 506 where the mask layer 620 is etched back until at least the portion 610a of the conductive layer 610 is exposed. In the present embodiments, an etching process is performed to remove an upper portion of the mask layer 620 to expose the portion 610a and expose am upper part of the portion 610b of the conductive layer 610. After the etching process, a portion 620p of the mask layer 620 remains in the funnel-shaped trench 232 and covers a portion of the conductive layer 610. The portion 620p of the mask layer 620 may be referred to the mask layer 620p.

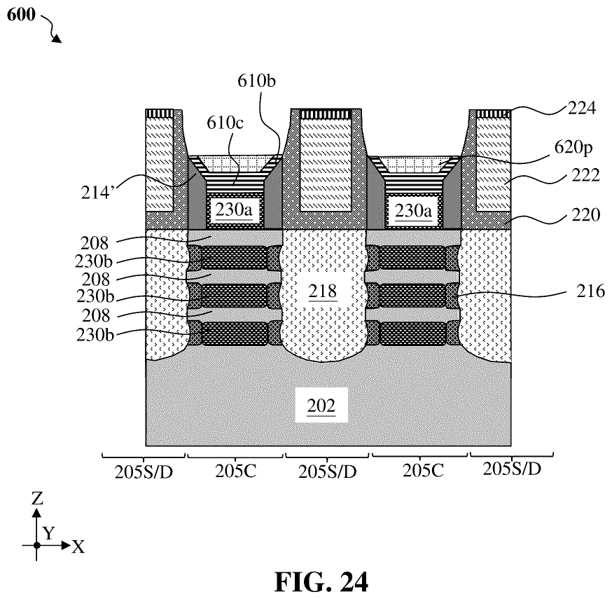

Referring to FIGS. 20 and 24, method 500 includes a block 508 where a portion of the conductive layer 610 not covered by the mask layer 620p is selectively removed. While using the mask layer 620p as an etch mask, an etching process is performed to selectively etch away the portion of the conductive layer 610 (e.g., the portion 610a and the upper part of the portion 610b of the conductive layer 610) not covered by the mask layer 620p, as illustrated in FIG. 24. The etching process may be a dry etch process, a wet etch process, or a suitable etch process.

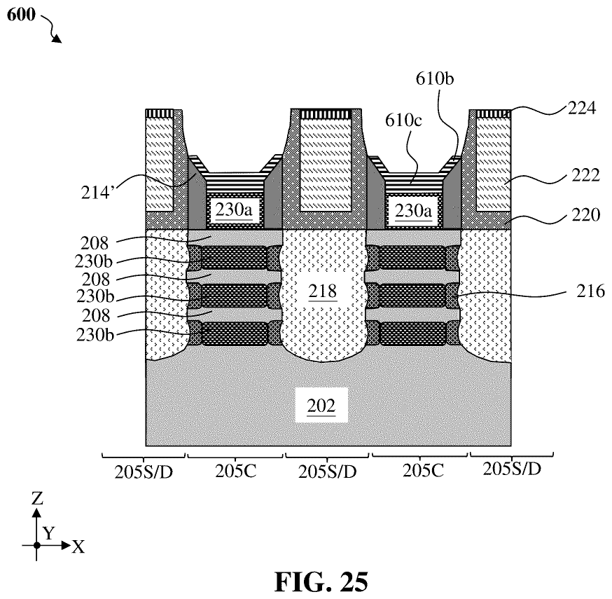

Referring to FIGS. 20 and 25, method 500 includes a block 510 where the mask layer 620p is selectively removed. After selectively removing the portion of the conductive layer 610 not covered by the portion 620p of the mask layer 620, the mask layer 620p is selectively removed using a suitable etching process. In embodiments represented in FIG. 25, after the removal of the mask layer 620p, the conductive layer 610 includes a lower part of the portion 610b on the top surface 214t of the gate spacers 214′ and the portion 610c on the top surface of the gate stack 230a.

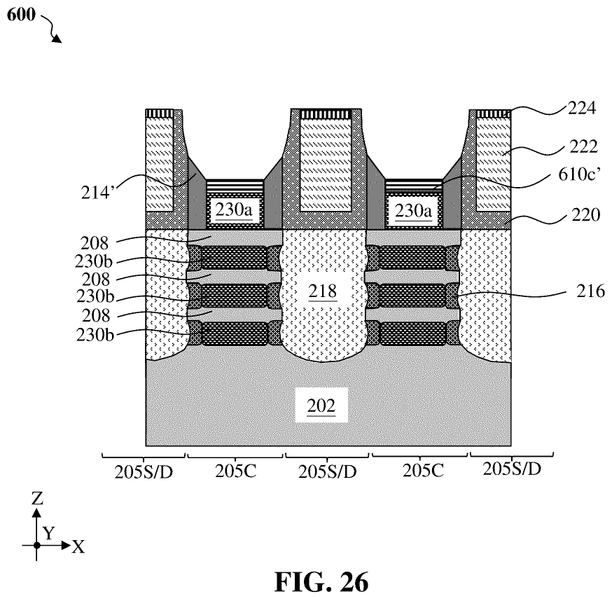

Referring to FIGS. 20 and 26, method 500 includes a block 512 where the conductive layer 610 is further etched back to form a metal cap 610c′ over the gate stack 230a. As described above, an isotropic etching process may be performed to selectively etch the conductive layer 610. The duration of the isotropic etching process may be controlled such that the portion 610b of the conductive layer 610 formed on the top surface 214t of the gate spacers 214′ is fully removed. Due to the performing of the isotropic etching process, the portion 610c of the conductive layer 610 is also slightly etched. The portion 610c of the conductive layer 610 after the performing of the isotropic etching process may be referred to as a first layer of a metal cap structure or a first metal cap 610c′. In an embodiment, along the Z direction, a thickness of the first metal cap 610c′ may be between about 1 nm and about 5 nm. Forming the first metal cap 610c′ may advantageously protect the gate stack 230a in subsequent etching processes (e.g., the etching process used to form the dielectric spacers 236).

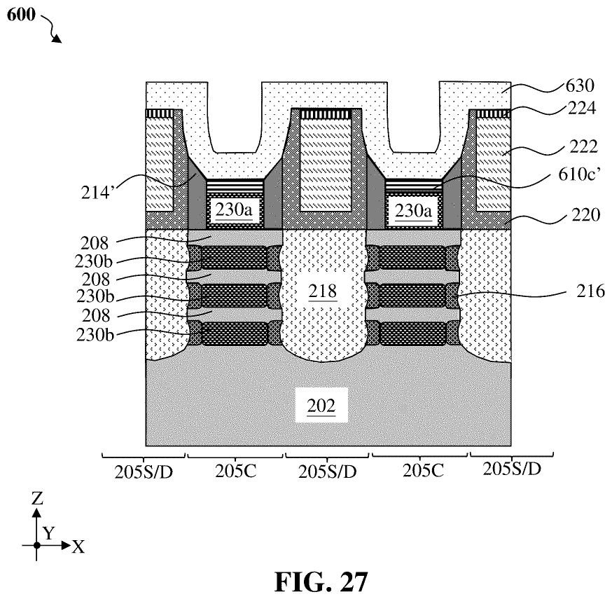

Referring to FIGS. 20 and 27, method 500 includes a block 514 where a dielectric layer 630 is conformally deposited over the workpiece 600. The composition and formation of the dielectric layer 630 is in a way similar to those of the dielectric layer 234, and repeated description is thus omitted for reason of simplicity. In an embodiment, a composition of the dielectric layer 630 is different from a composition of the gate spacer 214′.

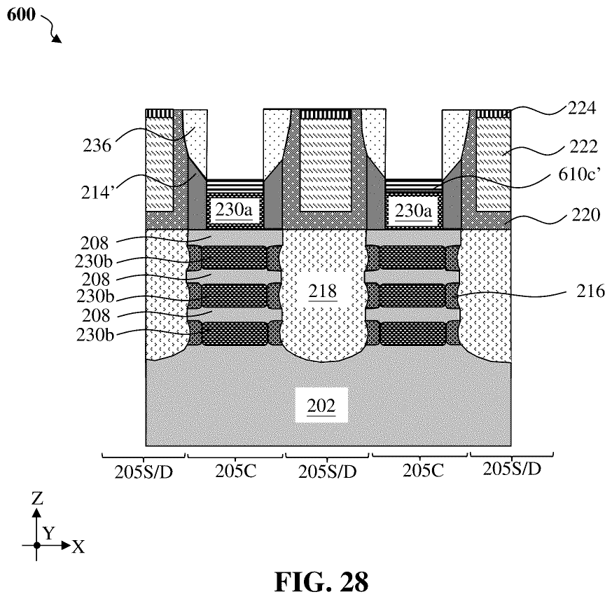

Referring to FIGS. 20 and 28, method 500 includes a block 516 where the dielectric layer 630 is etched back to form the dielectric spacers 236 in the funnel-shaped trench 232. In the present embodiments, the dielectric spacers 236 are not in direct contact with the first metal cap 610c′.

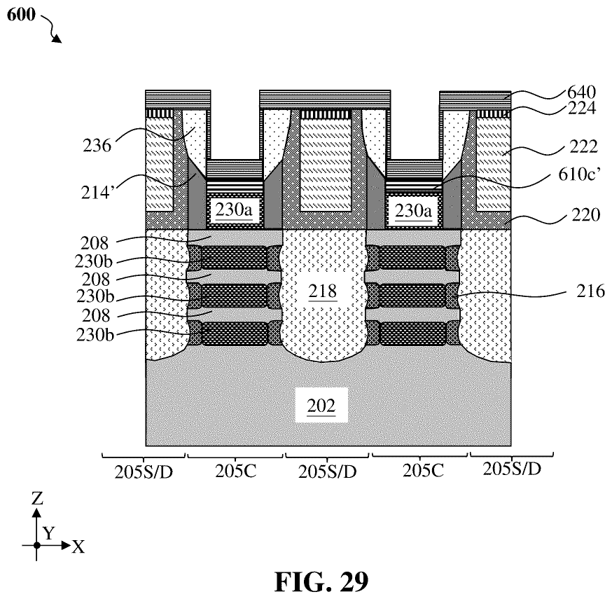

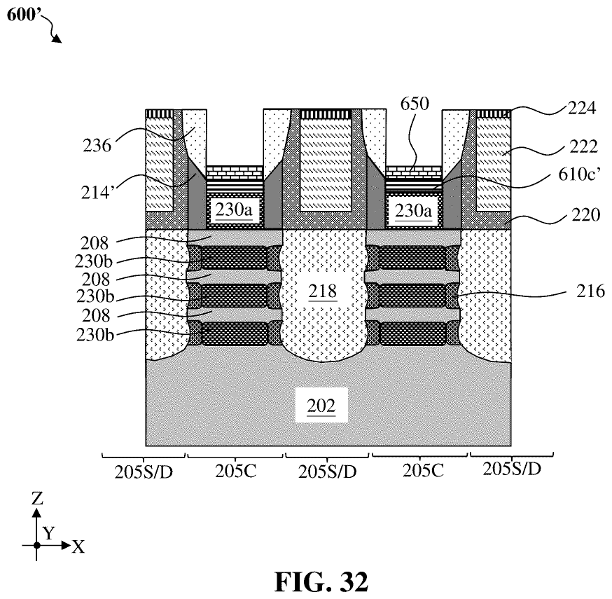

Referring to FIGS. 20, 29-30, and 32, method 500 includes a block 518 where a second metal cap is formed on the first metal cap 610c′. The second metal cap may also be referred to as a second layer of the metal cap structure. In an embodiment, the second metal cap may be formed in a way similar to the formation of the metal cap 410c′ described with reference to FIG. 18. More specifically, referring to FIG. 29, a second conductive layer 640 is formed on the workpiece 600 using a PVD process. A composition of the second conductive layer 640 may be the same as or different from a composition of the first conductive layer 610. After forming the second conductive layer 640, operations in blocks 304, 306, 308, 310, and 312 of method 300 may be performed to form a metal cap 640c′ in the workpiece 600. In an embodiment, a thickness of the metal cap 640c′ may be between about 1 nm and about 5 nm. In an embodiment, a top surface of the first metal cap 610c′ may be oxidized, and thus the workpiece 600 may include an oxide layer sandwiched between the first metal cap 610c′ and the metal cap 640c′. In other implementations, the second metal cap may be formed in a way similar to the formation of the metal cap 240 described with reference to FIG. 8. More specifically, in embodiments represented in FIG. 32, a metal cap 650 may be selectively formed on the metal cap 410c′ using the selective deposition process 238 described with reference to FIG. 8. In an embodiment, the metal cap 650 is a fluorine-free tungsten layer.

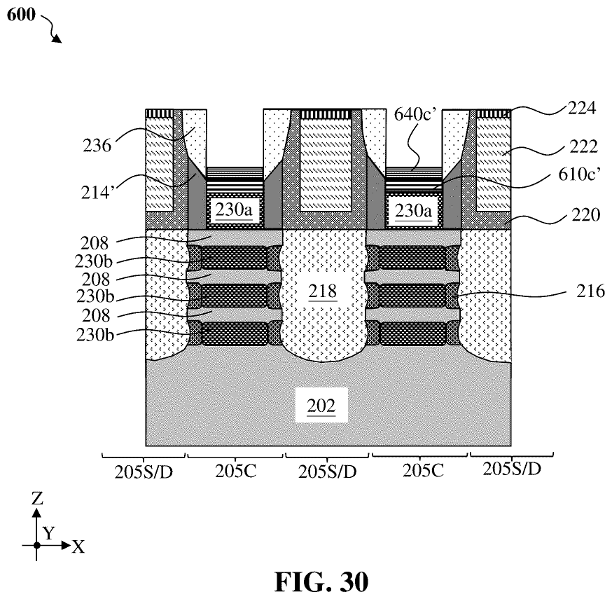

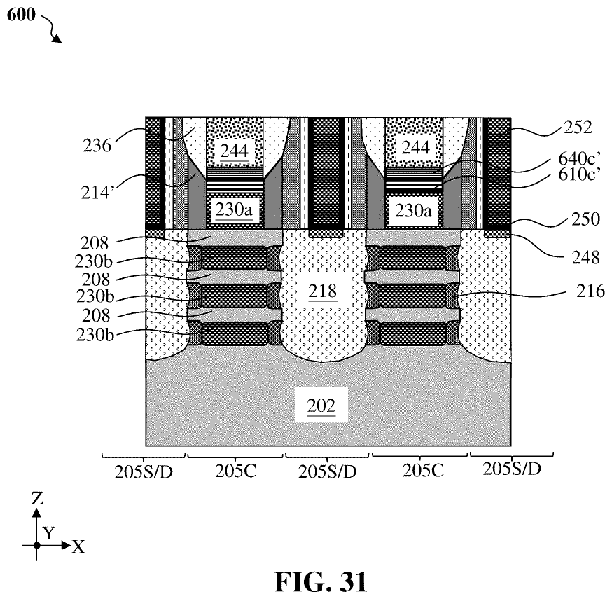

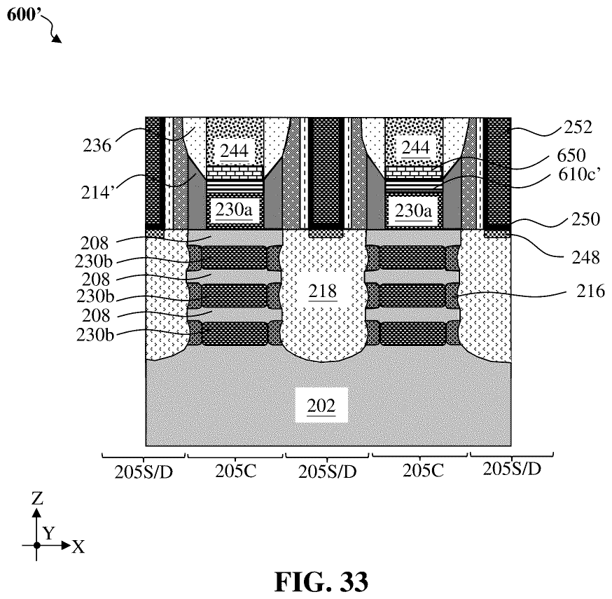

Referring to FIG. 20, FIG. 1, FIG. 31, and FIG. 33, after forming the second metal cap (e.g., the metal cap 640c′ in FIG. 30, or the metal cap 650 in FIG. 32), operations in blocks 118, 120, and 122 may be performed to finish the fabrication process. The workpiece 600 includes the metal cap 640c′ formed over the first metal cap 610c′, and the workpiece 600′ includes the metal cap 650 formed over the first metal cap 610c′.

In embodiments described above with reference to FIG. 20, the metal cap 610c′ is formed by a PVD deposited conductive layer 610. In some other implementations, the first metal cap may be formed by other processes. FIG. 34 illustrates an alternative method 700 of forming a semiconductor device having a first metal cap formed by a selective deposition process. Referring to FIG. 34 and FIG. 35, after forming the funnel-shaped trench 232 shown in FIG. 5, method 700 is performed. Method 700 includes a block 702 where a first metal cap 810 is selectively formed over the gate stack 230a. The formation and composition of the first metal cap 810 are in a way similar to those of the metal cap 240 described with reference to FIG. 8. In an embodiment, the first metal cap 810 is a fluorine-free tungsten layer. In the present embodiments, as indicated by the dashed lines, a top surface 810t of the first metal cap 810 is lower than the top surface 214t of the gate spacer 214′. In an embodiment, a thickness of the first metal cap 810 is between about 1 nm and about 5 nm.

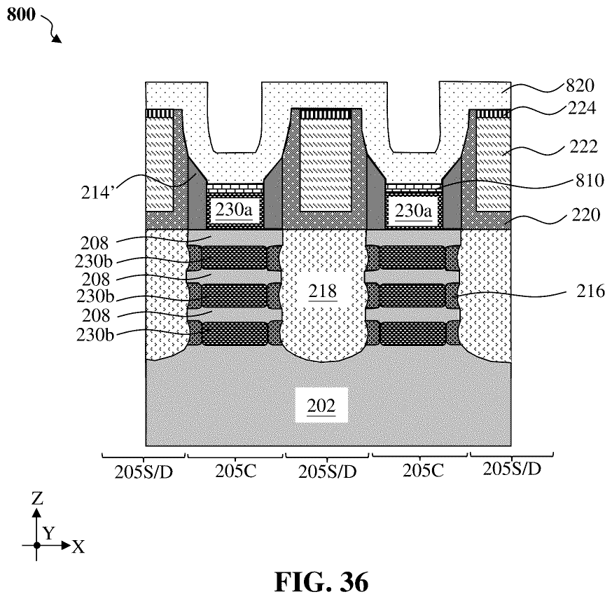

Referring to FIGS. 34 and 36, method 700 includes a block 704 where a dielectric layer 820 is formed over the workpiece. After forming the first metal cap 810, the dielectric layer 820 is conformally deposited over the workpiece 800. The composition and formation of the dielectric layer 820 is in a way similar to those of the dielectric layer 234, and repeated description is omitted for reason of simplicity. A composition of the dielectric layer 820 may be the same as or different from a composition of the gate spacer 214′.

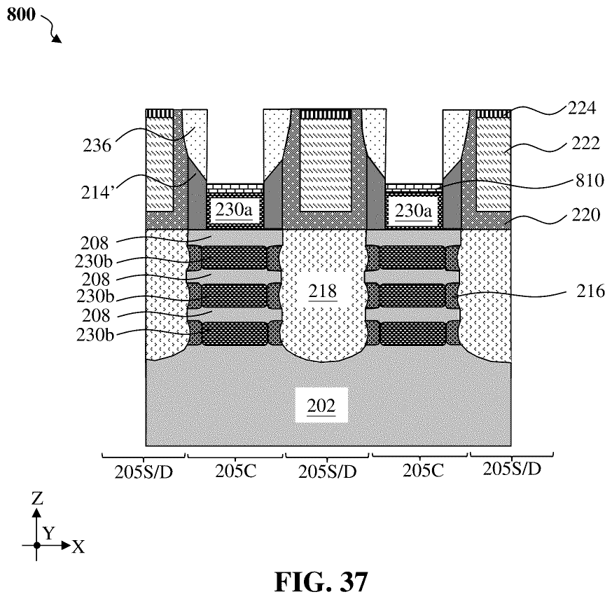

Referring to FIGS. 34 and 37, method 700 includes a block 706 where the dielectric layer 820 is etched back to form the dielectric spacers 236. In the present embodiments, the dielectric spacers 236 are not in direct contact with the first metal cap 610c′.

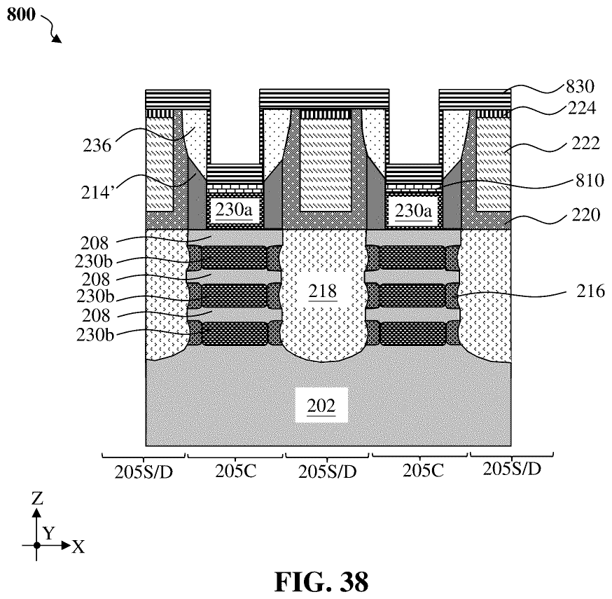

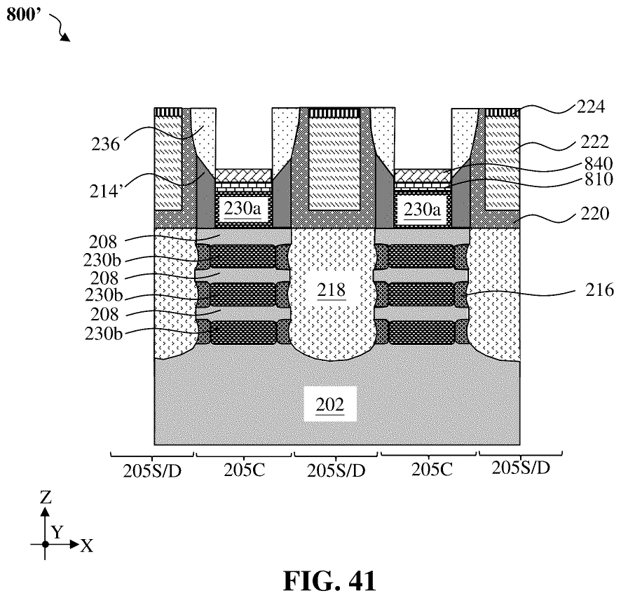

Referring to FIGS. 34, 38-39, and 41, method 700 includes a block 708 where a second metal cap is formed over the first metal cap 810. In an embodiment, the second metal cap may be formed in a way similar to the formation of the metal cap 410c′ described with reference to FIG. 19. More specifically, referring to FIG. 38, a conductive layer 830 is formed on the workpiece 800 using a PVD process. After forming the conductive layer 830, operations in blocks 304, 306, 308, 310, and 312 of method 300 may be performed to the workpiece 800 to form a metal cap 830c′ in the workpiece 800. In an embodiment, a thickness of the metal cap 830c′ may be between about 1 nm and about 5 nm. A composition of the first metal cap 810 may be the same as or different from a composition of the metal cap 830c′. In an embodiment, a top surface of the first metal cap 810 may be oxidized, and thus the workpiece 800 may include an oxide layer sandwiched between the first metal cap 810 and the metal cap 830c′. In other implementations, the second metal cap may be formed in a way similar to the formation of the metal cap 240 described with reference to FIG. 8. For example, in embodiments represented in FIG. 41, a metal cap 840 may be selectively formed on the first metal cap 810 using the selective deposition process 238 described with reference to FIG. 8. In an embodiment, the metal cap 840 is a fluorine-free tungsten layer.

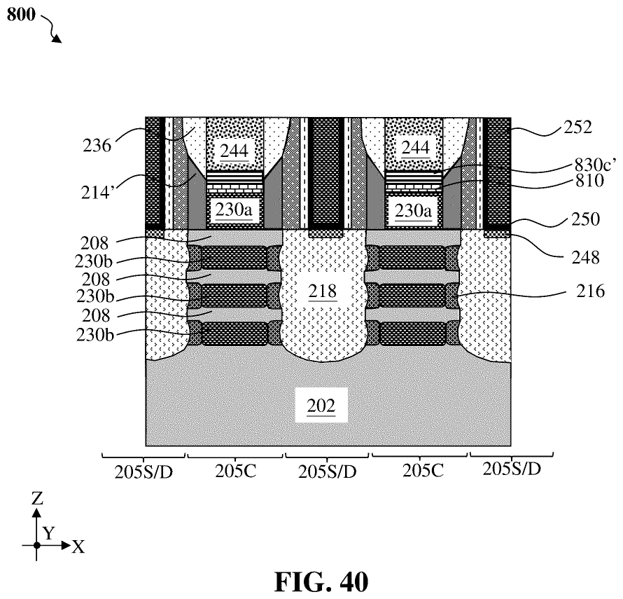

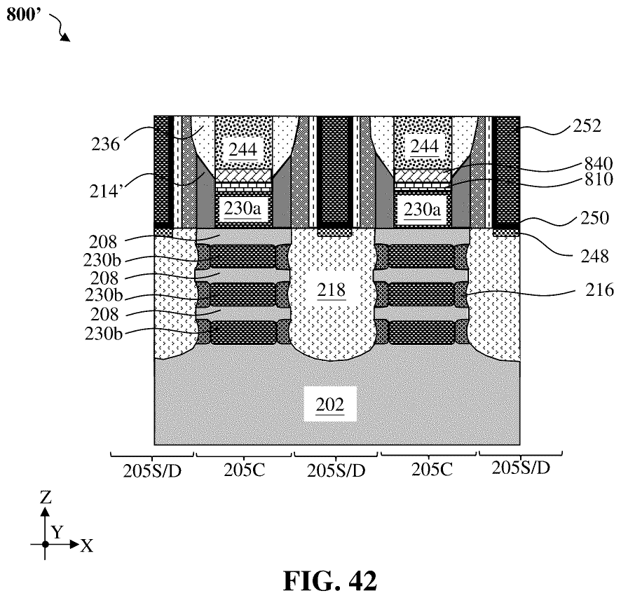

Referring to FIG. 34, FIG. 40, and FIG. 42, after forming the second metal cap (e.g., the metal cap 830c′ in FIG. 40, or the metal cap 840 in FIG. 42), operations in blocks 118, 120, and 122 of method 100 in FIG. 1 may be performed to finish the fabrication process. The workpiece 800 includes the metal cap 830c′ formed over the first metal cap 810, and the workpiece 800′ includes the metal cap 840 formed over the first metal cap 810.

Although not intended to be limiting, one or more embodiments of the present disclosure provide many benefits to a semiconductor device and the formation thereof. For example, the present disclosure provides methods for forming semiconductor devices with reduced parasitic capacitance and reduced leakage current by forming metal caps directly over gate stacks while not forming the metal caps vertically over gate spacers. The present disclosure also provides embodiments to implement a single-layer metal cap or a multi-layer metal cap in a semiconductor device. Forming a first layer of the multi-layer metal cap may protect the gate stack thereunder from subsequent etching processes. In some implementations, the methods of the present disclosure may be applied to form dielectric spacers and metal caps in FinFETs or planar transistors.

The present disclosure provides for many different embodiments. Semiconductor devices and methods of fabrication thereof are disclosed herein. In one exemplary aspect, the present disclosure is directed to a method. The method includes providing a workpiece including a channel region, a gate structure over the channel region, gate spacers extending along sidewalls of the gate structure, and an etch stop layer extending along sidewalls of the gate spacers. The method also includes performing an etching process to recess the gate spacers and the gate structure, thereby forming a funnel-shaped trench, depositing a dielectric layer over the workpiece to partially fill the funnel-shaped trench, etching back the dielectric layer to form dielectric spacers on the recessed gate spacers, forming a metal cap on the gate structure without forming the metal cap on the recessed gate spacers, and forming a dielectric cap on the metal cap.

In some embodiments, the performing of the etching process may also laterally remove a portion of the etch stop layer. In some embodiments, the etching back of the dielectric layer may include removing a portion of the dielectric layer on a top surface of the gate structure and a portion of the dielectric layer on a top surface of the etch stop layer. In some embodiments, the forming of the metal cap on the gate structure may include selectively forming a fluorine-free tungsten layer on the gate structure. In some embodiments, the method may also include, after the selectively forming of the fluorine-free tungsten layer on the gate structure, selectively forming another fluorine-free tungsten layer over the gate structure. In some embodiments, the depositing of the dielectric layer may be performed after the forming of the metal cap. The method may also include, after the selectively forming of the fluorine-free tungsten layer on the gate structure and after the etching back of the dielectric layer to form dielectric spacers, forming a conductive layer over the workpiece by a physical vapor deposition process, after forming the conductive layer, forming a mask layer over the workpiece, recessing the mask layer, thereby forming a recessed mask layer covering a bottom portion of the conductive layer, performing an etching process to selectively remove portions of the conductive layer not covered by the recessed mask layer, selectively removing the recessed mask layer, and etching back the bottom portion of the conductive layer to form another metal cap on the fluorine-free tungsten layer. In some embodiments, the forming of the metal cap on the gate structure may include, after the etching back of the dielectric layer, forming a conductive layer over the workpiece by a physical vapor deposition process, forming a mask layer over the workpiece, recessing the mask layer, thereby forming a recessed mask layer covering a bottom portion of the conductive layer, performing an etching process to selectively remove portions of the conductive layer not covered by the recessed mask layer, selectively removing the recessed mask layer, and etching back the bottom portion of the conductive layer to form the metal cap on the gate structure. In some embodiments, the method may include, after the etching back of the bottom portion of the conductive layer to form the metal cap, selectively forming a conductive layer on the gate structure without forming the conductive layer on the dielectric spacers.

In another exemplary aspect, the present disclosure is directed to a method. The method includes providing a workpiece including a gate stack and a gate spacer layer disposed on a sidewall of the gate stack, selectively removing an upper portion of the gate stack and an upper portion of the gate spacer layer to form an opening over the gate stack, wherein, in a cross-sectional view defined by a horizontal axis and a vertical axis, a profile of the opening comprises a funnel shape, after the selectively removing of the upper portion of the gate stack and the upper portion of the gate spacer layer, forming a dielectric spacer directly over the gate spacer layer, forming a metal cap directly over the gate stack, and forming a dielectric cap directly over the metal cap.

In some embodiments, the forming of the dielectric spacer may include conformally depositing a dielectric layer over the workpiece and removing a portion of the dielectric layer directly on the gate stack. In some embodiments, the workpiece may include a contact etch stop layer having a first portion in direct contact with the gate spacer layer and a second portion in direct contact with the dielectric spacer, and a sidewall surface of the second portion of the contact etch stop layer may curve inward. In some embodiments, the forming of the metal cap may include selectively forming the metal cap after the forming of the dielectric spacer. In some embodiments, the metal cap is a first metal cap, the method may include selectively forming a second metal cap on the first metal cap. In some embodiments, the forming of the metal cap may include, after the forming of the dielectric spacer, forming a conductive layer over the workpiece by a physical vapor deposition process, forming a mask layer over the workpiece to fill the opening, recessing the mask layer, thereby forming a recessed mask layer covering a bottom portion of the conductive layer, performing an etching process to selectively remove portions of the conductive layer not covered by the recessed mask layer, selectively removing the recessed mask layer, and etching back the bottom portion of the conductive layer to form the metal cap on the gate stack.

In yet another exemplary aspect, the present disclosure is directed to a semiconductor device. The semiconductor device includes a vertical stack of channel members disposed over a substrate, a gate structure comprising a first portion wrapping around each channel member of the vertical stack of channel members and a second portion disposed directly over the vertical stack of channel members. The gate structure includes a gate dielectric layer and a work function layer disposed over the gate dielectric layer. The semiconductor device also includes a conductive cap layer disposed directly over the second portion of the gate structure, a gate spacer extending along a sidewall surface of the second portion of the gate structure and a portion of a sidewall surface of the conductive cap layer, and a dielectric spacer disposed directly over the gate spacer. A width of a top surface of the dielectric spacer is greater than a width of the gate spacer.

In some embodiments, a width of the conductive cap layer may be uniform from bottom to top and may be substantially equal a width of the gate structure. In some embodiments, the semiconductor device may also include a dielectric cap layer disposed directly over the conductive cap layer. The dielectric spacer may be in direct contact with both the dielectric cap layer and the conductive cap layer. In some embodiments, a composition of the dielectric spacer may be different than a composition of the gate spacer. In some embodiments, a width the dielectric spacer may be not uniform from bottom to top. In some embodiments, a top surface of the gate spacer may be a tilted surface.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure. For example, by implementing different thicknesses for the bit-line conductor and word line conductor, one can achieve different resistances for the conductors. However, other techniques to vary the resistances of the metal conductors may also be utilized as well.

What is claimed is:

1. A semiconductor device, comprising:
a plurality of nanostructures over a substrate;
a gate structure comprising a first portion wrapping around the plurality of nanostructures and a second portion over the first portion;
a gate spacer extending along a sidewall surface of the second portion of the gate structure, wherein the gate spacer comprises a first sidewall surface interfacing the gate structure and a second sidewall surface opposite the first sidewall surface and further away from the gate structure, a height of the first sidewall surface is lower than a height of the second sidewall surface.

2. The semiconductor device of claim 1, wherein the gate spacer further comprises a top surface connecting the first sidewall surface and the second sidewall surface, wherein the top surface is a tilted surface.

3. The semiconductor device of claim 1, further comprising:
a conductive cap on the gate structure, wherein the gate spacer further extends along a portion of a sidewall surface of the conductive cap.

4. The semiconductor device of claim 3, further comprising:
a dielectric cap on the conductive cap.

5. The semiconductor device of claim 4, further comprising:
a dielectric spacer on the gate spacer, wherein the dielectric spacer extends along a sidewall of the dielectric cap.

6. The semiconductor device of claim 5, wherein a top surface of the dielectric spacer spans a first width, a bottom surface of the gate spacer spans a second width less than the first width.

7. The semiconductor device of claim 1, further comprising:
source/drain features coupled to the plurality of nanostructures.

8. The semiconductor device of claim 7, further comprising:
inner spacers disposed between the first portion of the gate structure and the source/drain features.

9. A semiconductor device, comprising:
an active region comprising a channel region and a source/drain region;
a gate structure disposed over the channel region;
a gate spacer disposed along a sidewall of the gate structure;
a source/drain feature disposed over the source/drain region;
a contact etch stop layer (CESL) disposed over the source/drain feature;
an interlayer dielectric (ILD) layer disposed over the CESL, wherein a portion of the CESL extends along a sidewall of the gate spacer such that the gate spacer is disposed between the gate structure and the CESL, wherein the gate structure comprises a gate dielectric layer and a gate electrode over the gate dielectric layer, wherein a dielectric constant of the gate dielectric layer is greater than a dielectric constant of the gate spacer;
a dielectric spacer on the gate spacer and spaced apart from the gate structure, wherein a top surface of the dielectric spacer spans a first width, a bottom surface of the gate spacer spans a second width less than the first width.

10. The semiconductor device of claim 9, wherein the dielectric spacer interfaces with the CESL.

11. The semiconductor device of claim 9, wherein the dielectric spacer is further vertically overlapped with a portion of the CESL.

12. The semiconductor device of claim 9, wherein an interface between the dielectric spacer and the CESL is curved.

13. The semiconductor device of claim 9, further comprising:
a metal cap disposed on the gate structure; and
a dielectric cap disposed on the metal cap, wherein the dielectric spacer interfaces with the dielectric cap and the metal cap.

14. The semiconductor device of claim 13, wherein a top surface of the metal cap is coplanar with a top surface of the dielectric spacer.

15. A semiconductor device, comprising:
a vertical stack of channel members disposed over a substrate;
a gate structure comprising a first portion wrapping around the vertical stack of channel members and a second portion disposed over the vertical stack of channel members, the gate structure comprising:
a gate dielectric layer, and
a work function layer disposed over the gate dielectric layer;
a conductive cap disposed over the second portion of the gate structure;
a gate spacer extending along a sidewall surface of the second portion of the gate structure and a lower portion of a sidewall surface of the conductive cap; and
a dielectric spacer disposed over the gate spacer, wherein the dielectric spacer extends along an upper portion of the sidewall surface of the conductive cap.

16. The semiconductor device of claim 15, wherein a width of the conductive cap is uniform from bottom to top and is substantially equal a width of the gate structure.

17. The semiconductor device of claim 15, further comprising:
a dielectric cap disposed over the conductive cap, wherein the dielectric spacer further extends along a sidewall surface of the dielectric cap.

18. The semiconductor device of claim 17, wherein a composition of the dielectric spacer is different than a composition of the gate spacer.

19. The semiconductor device of claim 17, wherein a width of the dielectric spacer is not uniform from bottom to top.

20. The semiconductor device of claim 15, wherein a top surface of the gate spacer tilts downward towards the second portion of the gate structure.
